(19) United States
(12) Patent Application Publication
(10) Pub. No.: US 2017/0351456 A1
(43) Pub. Date: Dec. 7, 2017

(54) MEMORY MODULE USED IN A WELL OPERATION

(71) Applicants: Falko Beulshausen, Niedersachsen (DE); Matthias Gatzen, Isernhagen (DE); Marius Kluge, Hannover (DE); Ole-Hendrik Ohlendorf, Hannover (DE); Wido Kunde, Eschede (DE); Sebastian Tegeler, Hannover (DE); Andre Koenecke, Nienhagen (DE); Annabelle Gosewisch, Eicklingen (DE); Thomas Kruspe, Kruspe (DE)

(72) Inventors: Falko Beulshausen, Niedersachsen (DE); Matthias Gatzen, Isernhagen (DE); Marius Kluge, Hannover (DE); Ole-Hendrik Ohlendorf, Hannover (DE); Wido Kunde, Eschede (DE); Sebastian Tegeler, Hannover (DE); Andre Koenecke, Nienhagen (DE); Annabelle Gosewisch, Eicklingen (DE); Thomas Kruspe, Kruspe (DE)

(73) Assignee: Baker Hughes Incorporated, Houston, TX (US)

(21) Appl. No.: 15/171,161

(22) Filed: Jun. 2, 2016

(51) Int. Cl. G06F 3/06; G06F 11/10; G11C 29/52

(52) U.S. Cl. CPC G06F 3/0634; G11C 29/52; G06F 11/1068; G06F 3/0619; G06F 3/0653; G06F 3/0679

(57) ABSTRACT

Examples of high-temperature memory modules used in a well operation are disclosed. In one example implementation according to aspects of the present disclosure, a memory module may include: a control unit configured to receive data from a controller in the well operation and further configured to receive an operating temperature downhole in the well operation and to cause the control unit to initiate a shutdown of the memory module if the operating temperature is greater than a first threshold; and a memory controller configured to receive the data from the control unit and to commit the data to storage medium.

### BACKGROUND

The present disclosure relates to well operations and, more particularly, to a memory module used in a well operation.

Boreholes are drilled into earth formations having reservoirs of hydrocarbons in order to extract the hydrocarbons through the boreholes to the surface. Various components (e.g., pipe segments, pipe couplings, pipe valves, manifolds, etc.) connect equipment (e.g., blending equipment, pumping equipment, etc.) at the earth's surface to the bore holes. The components that connect the equipment to the boreholes carry fluid, such as drilling fluid, to the boreholes to be used to extract the hydrocarbons through the boreholes. The drilling fluid may be a mixture of solids (e.g., sand) and liquids (e.g., water). Over time, the drilling fluid may cause damage to or otherwise degrade the components, thereby shortening the useful life of a component and/or leading to catastrophic failure of a component. Moreover, temperatures downhole in the borehole may cause equipment failure of electronic components, such as sensors, memory, controllers, and the like.

### BRIEF SUMMARY

According to aspects of the present disclosure, techniques including methods, systems, and/or computer program products for identifying and determining wear of a component used in a well operation are provided. An example memory module may include: In one example implementation according to aspects of the present disclosure, a memory module may include: a control unit configured to receive data from a controller in the well operation and further configured to receive an operating temperature downhole in the well operation and to cause the control unit to initiate a shutdown of the memory module if the operating temperature is greater than a first threshold; and a memory controller configured to receive the data from the control unit and to commit the data to storage medium.

According to additional aspects of the present disclosure, another example memory module may include: a control unit and memory controller configured to receive data from a controller in the well operation and further configured to receive an operating temperature downhole in the well operation and to cause the control unit to initiate a shutdown of the memory module if the operating temperature is greater than a first threshold.

According to yet additional aspects of the present disclosure, a method for writing and reading data via a memory module used in a well operation may include: receiving, at the memory module, write data from a controller at the well operation; writing, by a memory controller, the write data to a storage medium; receiving, via a communication interface, a request to read the data from the storage medium; transmitting, via the communication interface, the data responsive to the request; monitoring an operating temperature downhole in the well operation; and causing the memory module to initiate a shutdown of the memory module if the operating temperature is greater than a first threshold.

Additional features and advantages are realized through the techniques of the present disclosure. Other aspects are described in detail herein and are considered a part of the disclosure. For a better understanding of the present disclosure with the advantages and the features, refer to the following description and to the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages thereof, are apparent from the following detailed description taken in conjunction with the accompanying drawings in which:

FIG. 1 illustrates a block diagram of a high-temperature memory module used in a well operation according to aspects of the present disclosure;

FIG. 2 illustrates a block diagram of a high-temperature memory module used in a well operation according to aspects of the present disclosure;

FIG. 3 illustrates is a cross-sectional view of a borehole penetrating the earth having a formation, which contains a reservoir of hydrocarbons, according to examples of the present disclosure; and

FIG. 4 illustrates a flow diagram of a method for writing and reading data via a memory module used in well operation according to examples of the present disclosure.

### DETAILED DESCRIPTION

Various implementations are described below by referring to several examples of a memory module used in a well operation. Downhole data may be collected before, during, and/or after the extraction of hydrocarbons through the boreholes to the surface. For example, downhole equipment may be equipped with sensors or other data collection devices to collect data relating to the well operation, the hydrocarbons, the earth formation, etc. Current downhole data quality is limited due to the very high temperatures (approximately 130° C. to 150° C. or higher) downhole. In particular, hardware limitations and error correction methods currently implemented may fail or be insufficient at these temperatures. For example, existing 1-bit data correction may be insufficient to recover from memory failures caused by the high-temperature environment.

The present techniques increase the quality of downhole data by providing a higher bit data correction (e.g., 8 bit, 12 bit, etc.) to enable recovery from memory failures caused by the high-temperature environment. Higher bit data correction provides better error correction and wear-leveling in the high-temperature environment, making the memory more reliable. The present techniques also improve the reliability of the memory module by shutting down the memory module if temperatures become too high to operate reliably or when temperatures may cause damage to the memory module and/or the data. In addition, the present techniques provide for significantly increased data transfer over existing implementations by implementing Ethernet and/or USB data transfer directly from the memory module. By using the Ethernet and/or USB data transfer, data transfer speed is significantly increased. For example, data transfer may occur approximately 20 times faster than in traditional memory modules used in well operations. Moreover, the present techniques enable the memory module to be powered directly from a USB port of a processing device (i.e., a computer) when the data are read, such as at the surface of the well operation. These and other advantages will be apparent from the description that follows.

The teachings of the present disclosure can be applied in a variety of well operations. These operations may involve using one or more treatment agents to treat a formation, the fluids resident in a formation, a wellbore, and/or equipment in the wellbore, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

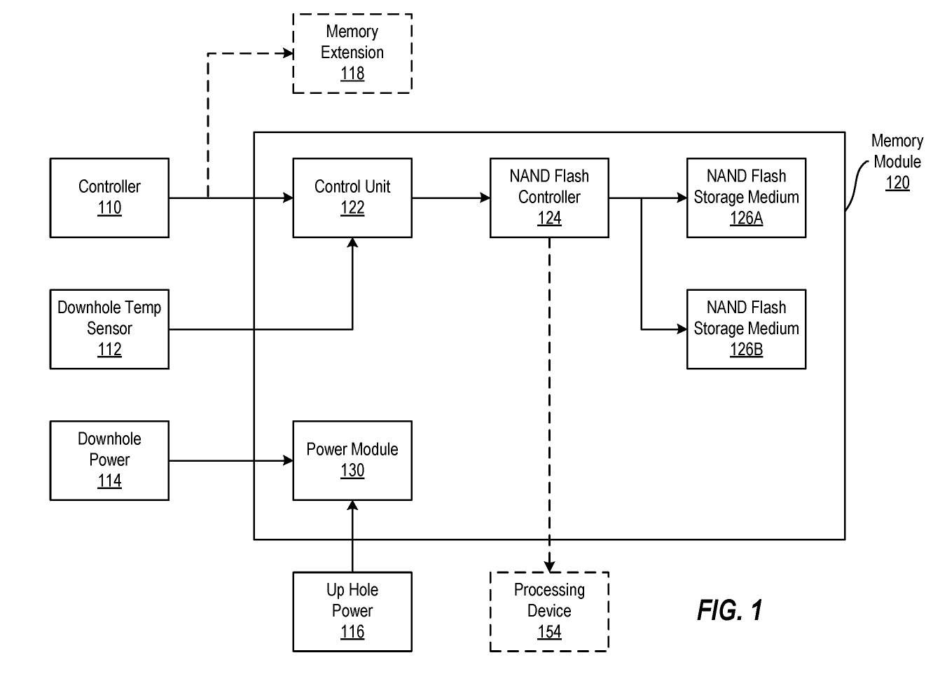

FIG. 1 illustrates a block diagram of a high-temperature memory module 120 used in a well operation according to aspects of the present disclosure. The memory module receives data from a controller 110 that may collect the data from a sensor or sensors (e.g., pressure sensors, temperature sensors, flow sensors, viscosity sensors, pH sensors, etc.). In some examples, a communication interface between the controller 110 and the memory module 120 utilizes the serial peripheral interface (SPI) protocol, although other suitable protocols, such as a parallel interface, may be used.

The data are received in a control unit 122 of the memory module 120 and are transferred to a memory controller, such as NAND flash controller 124. The control unit may be a field-programmable gate array (FPGA), an application-specific integrated circuit (ASIC), digital signal processing system, or other suitable component. The NAND flash controller 124 commits the data to a storage medium, such as NAND flash storage medium 126A, 126B. It should be appreciated that, although the present example utilizes NAND flash storage mediums and a NAND flash memory controller, other types of non-volatile memory, may be implemented. It should also be appreciated that, although two NAND flash storage mediums 126A, 126B are illustrated, fewer or more storage mediums may be implemented in other examples. NAND flash provides increased storage density resulting in high downhole memory storage capacity in a small physical space. In examples of the present disclosure, the NAND flash storage medium 126A, 126B may be removable, such as for maintenance or replacement.

According to aspects of the present disclosure, the NAND flash controller 124 provides bad block handling, wear leveling, and/or error correction for the NAND flash storage medium 126A, 126B. In the case of error correction, the NAND flash controller 124 may utilize more than 1 bit. For example, error correction may utilize 4 bits, 8 bits, 12 bits, 16 bits, or another suitable number of bits. By using, for example, 12 bit error correction, the NAND flash controller 124 can provide better error correction to the memory module 120 to enable the memory module 120 to operate reliably in high-temperature environments, such as downhole in a well operation.

The control unit 122 also receives data from a downhole temperature sensor 112 that collects temperature data downhole at the well operation and transmits the temperature data to the control unit 122. In examples, the control unit 122 can itself request the temperature from the downhole temperature sensor 112 periodically (e.g., every second, every ten seconds, every minute, etc.) or may receive an interrupt from the temperature sensor 112 when a certain temperature is reached. The control unit 122 compares the temperature data to a threshold that may be set, for example, by a system administrator or automatically by another device. If the temperature data indicates a temperature in excess of the threshold, the control unit 122 sends a shutdown signal to the memory controller and/or the NAND flash storage medium 126A, 126B. The shutdown may cause the NAND flash controller 124 and the NAND flash storage medium 126A, 126B to enter a write protect mode to preserve the data stored on the NAND flash storage medium 126A, 126B. In other examples, the shutdown also includes causing the memory module 120 to enter an off mode in which the memory module 120 shuts down or powers down.

According to aspects of the present disclosure, control unit 122 may utilize multiple temperature thresholds. For example, the threshold discussed above may be a first threshold to cause the control unit 122 to initiate a shutdown of the memory module 120 to include causing the NAND flash controller 124 and the NAND flash storage medium 126A, 126B to enter a write protect mode. A second threshold may be implemented to cause the memory module 120 to transmit a warning to a user if the temperature is greater than a second threshold. In this example, the first threshold is greater than the second threshold such that a warning is issued at the second (lower) threshold and then the shutdown is imitated at the first (higher) threshold. Additional thresholds may also be implemented.

The memory module 120 may also include a power module 130 to receive downhole power 114 when the memory module is positioned downhole. The downhole power 114 may be a low-voltage power supply or other suitable power supply located downhole to power the memory module 120 while data are being written to the memory module 120 from the controller. The up hole power 116 may be another low-voltage power supply or other suitable power supply located up hole (at the surface) to power the memory module 120 while data are being read from the memory module 120, such as by a processing device (i.e., a computer). In examples, the processing device may supply the up hole power 116 to the power module 130, such as via a USB, power over Ethernet, or other suitable connection. This enables a single cable to be connected between the processing device and the memory module 120 to power the memory module 120 and to read data from the memory module 120. The power module 130 powers the memory module 120.

The memory module 120 may also be connectable to a memory extension 118 to expand the memory/storage of the memory module 120. For example, the memory extension 118 may be an additional memory module like memory module 120 or may be additional storage medium such as NAND flash storage medium 126A, 126B. The controller 110 may manage the memory extension 118 in examples of the present disclosure. The memory extension 118 may also provide redundancy such that data can be written to the memory extension 118 to mirror the data written to the NAND flash storage medium 126A, 126B.

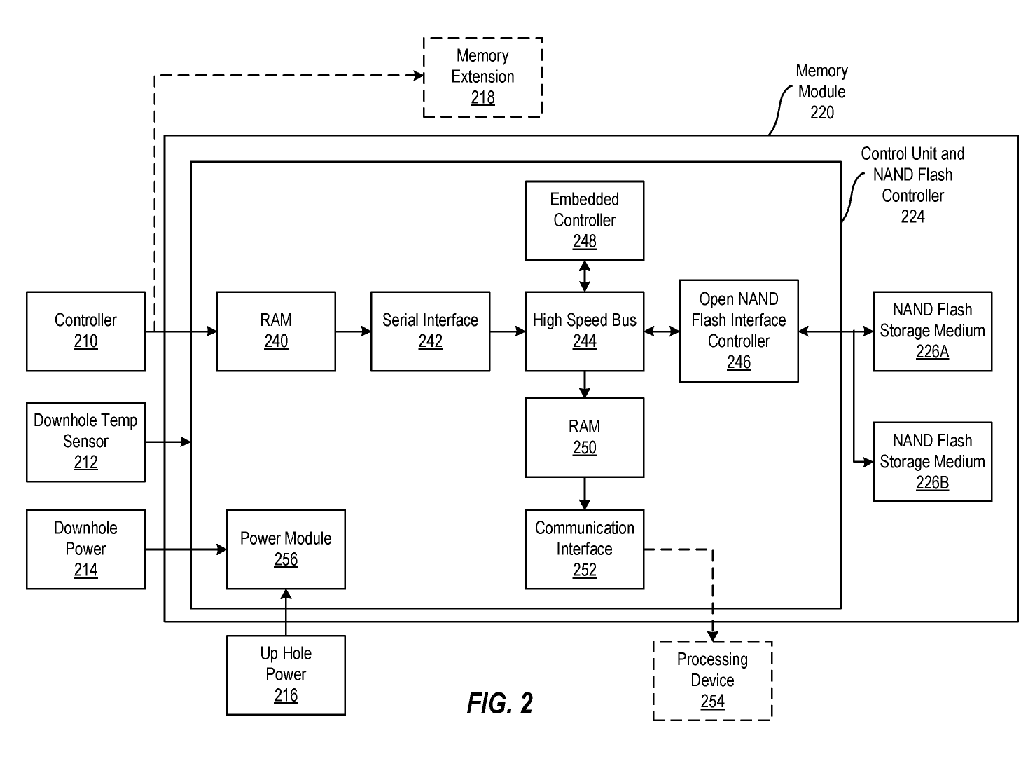

In examples, the memory module 120 transmits data to a processing device 154, which may be any suitable processing device (i.e., a laptop computer, a desktop computer, a smartphone, a tablet computer, a special purpose computer, etc.). The processing device 154 connects to a communication interface (such as communication interface 252 of FIG. 2), which may be a USB communication interface, an Ethernet communication interface, or any other suitable communication interface.

It should be appreciated that the primary function of the control unit 122 is to collect incoming data and prepare the data for the NAND flash controller 124. In aspects of the present disclosure, the NAND flash controller 124 provides at least one of the following functionalities: acting as an open NAND flash interface (ONFI) controller, providing a USB interface, an Ethernet interface, or other suitable interface for connecting a processing device, providing bad block handling, providing wear leveling, providing error correction (e.g., 12 bit error correction), and providing status bit provisioning. Regarding status bit provisioning of the memory module, the status bits can be utilized, individually or with the temperature data sensed downhole, for downhole tool diagnostics, such as lifetime prediction, maintenance cycle calculations, number of bit failures (i.e., number of corrected bits), available memory capacity, wear level status, number of read/write cycles, health status, etc. In examples, each data transfer (both read and write) is protected with a checksum to ensure data is correct. In the event of a checksum error, the data may automatically be sent again, for example, a certain number of times before an error message is returned or the data is identified/labeled as bad.

Turning now to FIG. 2, FIG. 2 illustrates a block diagram of a memory module 220 used in a well operation according to aspects of the present disclosure. The memory module 220 includes a control unit and NAND flash controller 224 to manage data reads and data writes from and to NAND flash storage medium 226A, 226B (or other suitable memory).

During data writes, such as when the memory module 220 is downhole, the memory module 220 receives data from a controller 210 which collects data, such as tool/service data from downhole equipment used in the well operation. The data may be received using any suitable interface, such as an SPI or a parallel interface. In some examples, the data are received into a RAM 240. The data are transferred via a serial interface 242 and a high-speed bus 244 to an open NAND flash interface (ONFI) controller 246.

The ONFI controller 246 commits the data to a storage medium, such as NAND flash storage medium 226A, 226B. It should be appreciated that, although the present example utilizes NAND flash storage mediums and a NAND flash memory controller, other types of memory, and in particular non-volatile memory, may be implemented. It should also be appreciated that, although two NAND flash storage mediums 226A, 226B are illustrated, fewer or more storage mediums may be implemented in other examples.

During data reads, such as when the memory module 220 is up hole (i.e., at the earth's surface), the memory module 220 transmits data to a processing device 254, which may be any suitable processing device (i.e., a laptop computer, a desktop computer, a smartphone, a tablet computer, a special purpose computer, etc.). The processing device 254 connects to a communication interface 252, which may be a USB communication interface, an Ethernet communication interface, or any other suitable communication interface. The communication interface 252 may also be responsible for receiving power to supply power from the processing device 254 to the power module 256.

The data are requested via the processing device 254 and are retrieved from the NAND flash storage medium 226A, 226B via the ONFI controller 246. The data are transferred into RAM 250 (in some examples) via the high-speed bus 244 and are then sent to the processing device 254 via the communication interface 252. The embedded controller 248 could be used to realize internal NAND flash controller operations, as for example the high speed bus 244 and the communication interface 252.

Although not illustrated, a physical layer (PHY) Ethernet transceiver and a transformer may be used to facilitate communications between the communication interface 252 and the processing device 254 according to aspects of the present disclosure.

The control unit and NAND flash controller 224 also receives data from a downhole temperature sensor 212 that collects temperature data downhole at the well operation and transmits the temperature data to the control unit and NAND flash controller 224. In examples, the control unit and NAND flash controller 224 can itself request the temperature from the downhole temperature sensor 212 periodically (e.g., every second, every ten seconds, every minute, etc.) or may receive an interrupt from the temperature sensor 212 when a certain temperature is reached. The control unit and NAND flash controller 224 compares the temperature data to a threshold that may be set, for example, by a system administrator or automatically by another device. If the temperature data indicates a temperature in excess of the threshold, the control unit and NAND flash controller 224 sends a shutdown signal to the NAND flash storage medium 226A, 226B. The shutdown may cause the control unit and NAND flash controller 224 and the NAND flash storage medium 226A, 226B to enter a write protect mode to preserve the data stored on the NAND flash storage medium 226A, 226B. In other examples, the shutdown also includes causing the memory module 220 to enter an off mode in which the memory module 220 shuts down or powers down.

The memory module 220 may also include a power module 256 to receive power, such as from low-voltage power supply or other suitable power supply located downhole (e.g., downhole power 214) or up hole (e.g., up hole power 216) or via a USB, power over Ethernet, or other suitable connection. This enables a single cable to be connected between the processing device 254 and the memory module 220 to power the memory module 220 and to read data from the memory module 220. The power module 256 powers the memory module 220.

In additional examples, a memory extension 218 may be utilized to provide additional storage and/or to provide redundancy. In examples, the memory extension 218 and/or the NAND flash storage medium 226A, 226B are exchangeable, such as when the components reach an end-of-life or a lifetime. This enables the memory extension 218 and/or the NAND flash storage medium 226A, 226B to be replaced by another memory extension and/or NAND flash storage medium respectively.

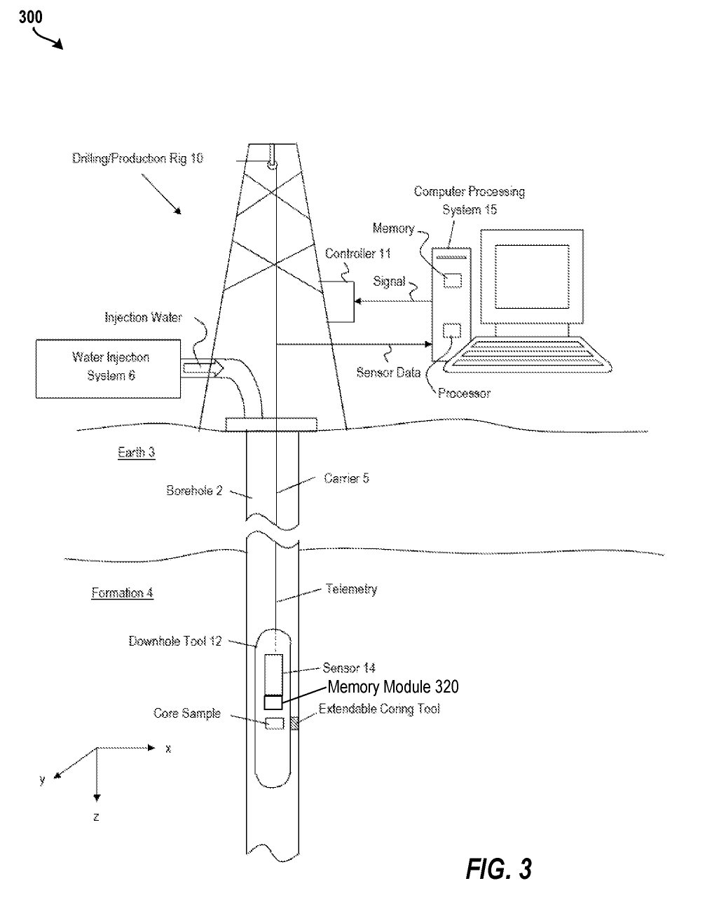

FIG. 3 illustrates is a cross-sectional view of a borehole 2 (may also be referred to as a well) penetrating the earth 3 having a formation 4, which contains a reservoir of hydrocarbons, according to examples of the present disclosure. The borehole 2 may be vertical or deviated or horizontal. A drilling/production rig 10 is configured to drill the borehole 2 and/or perform completion and production actions relating to extracting hydrocarbons from the formation 4. The drilling/production rig 10 includes a controller 11 configured to control various operations performed by the drilling/production rig 10 such as controlling a pumping rate and corresponding duration for water injection purposes. The controller 11 is further configured to receive a signal, such as from a computer processing system 15, providing the controller 11 with instructions, such as a set point or operating curve for example, for controlling the various operations. In some examples, an additional controller (e.g., controller 110 of FIG. 1) is located downhole at the well operation and communicates with the memory module 320. As illustrated in FIG. 3, a memory module 320 may be installed in the borehole 2 at the well operation 300 to collect data as described herein.

A casing 5 such as a drill tubular or drill string for drilling the borehole 2 or an armored wireline for wireline logging embodiments may be disposed in the borehole 2 along with the memory module 320. A downhole tool 12 is conveyed through the borehole by the carrier 5. The downhole tool 12 includes a sensor 14 for sensing a property of the borehole 2 or formation 4.

In addition, the downhole tool 12 may be configured to extract a core sample from the formation 4 using an extendable coring tool. The core sample may be analyzed downhole using the sensor 14 to determine one or more properties or parameters of the core sample and thus the formation 4 or it may be analyzed in a laboratory at the surface using micro-photography or X-ray techniques for example. The information determined from the core sample and/or formation logging measurements may be used to determine the discrete fracture network (DFN) of the formation 4. Sensed downhole properties or parameters may be transmitted to the computer processing system 15 using telemetry, which can be the armored wireline, pulsed-mud, or wired drill pipe as non-limiting embodiments. The drilling production rig 10 may also include a water injection system 6 controllable by the controller 11 for injecting water into the formation 4.

In support of the teachings herein, various analysis components may be used, including a digital and/or an analog system. For example, the drilling/production rig 10, controller 11, the downhole tool 12, the sensor 14, and/or the computer processing system 15 may include digital and/or analog systems. The system may have components such as a processor, storage media, memory, input, output, communications link (wired, wireless, pulsed mud, optical or other), user interfaces, software programs, signal processors (digital or analog) and other such components (such as resistors, capacitors, inductors and others) to provide for operation and analyses of the apparatus and methods disclosed herein in any of several manners well-appreciated in the art. It is considered that these teachings may be, but need not be, implemented in conjunction with a set of computer executable instructions stored on a non-transitory computer readable medium, including memory (ROMs, RAMs), optical (CD-ROMs), or magnetic (disks, hard drives), or any other type that when executed causes a computer to implement the method of the present invention. These instructions may provide for equipment operation, control, data collection and analysis and other functions deemed relevant by a system designer, owner, user or other such personnel, in addition to the functions described in this disclosure.

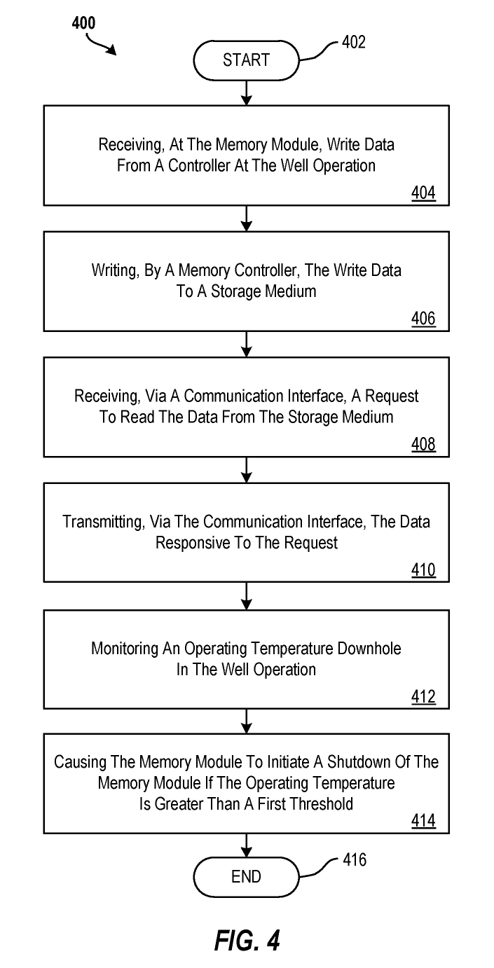

FIG. 4 illustrates a flow diagram of a method 400 for writing and reading data via a memory module used in well operation according to examples of the present disclosure. The method 400 may be performed by a memory module, such as the memory module 120 of FIG. 1, the memory module 220 of FIG. 2, and/or the memory module 320 of FIG. 3. The method 400 starts at block 402 and continues to block 404.

At block 404, the method 400 includes receiving, at the memory module, write data from a controller at the well operation. At block 406, the method 400 includes writing, by a memory controller, the write data to a storage medium. In examples, the memory controller is an ONFI controller.

At block 408, the method 400 includes receiving, via a communication interface, a request to read the data from the storage medium (e.g., a NAND flash storage medium). It should be appreciated that the communication interface may be an Ethernet interface, a USB interface, or another suitable communication interface. In the case of a USB interface, the USB interface may also provide power to the memory module.

At block 410, the method 400 includes transmitting, via the communication interface, the data responsive to the request. At block 412, the method 400 includes monitoring an operating temperature downhole in the well operation.

At block 414, the method 400 includes causing the memory module to initiate a shutdown of the memory module if the operating temperature is greater than a first threshold. A control unit (e.g., control unit 122 of FIG. 1) or another suitable temperature controller may transmit a warning to a user if the operating temperature is greater than a second threshold. In this case, the first threshold is greater than the second threshold such that the second threshold acts as a warning before the first threshold is reached and the shutdown is initiated. In examples, initiating the shutdown includes causing the memory controller and the storage medium to enter a write protect mode.

The method 400 continues to block 416 and ends. However, additional processes also may be included, and it should be understood that the processes depicted in FIG. 4 represent illustrations, and that other processes may be added or existing processes may be removed, modified, or rearranged without departing from the scope and spirit of the present disclosure.

Memory modules show limited lifetime exposed to high downhole temperatures. Measures are necessary to avoid data loss and data corruption in downhole memory modules. Redundancy of memory modules, tracking of lifetime and preventive maintenance are additional measures that should be taken to use memory modules under high temperature conditions.

It should be appreciated that the physical replacement of memory modules should be simplified by the mechanical design of the downhole tool, in order to facilitate a fast replacement of used memory modules. A memory module that is prone to failure may be easily replaceable after having reached the predicted lifetime or after it shows erroneous behavior. The replacement may be feasible even on the rig-site. The design may facilitate a replacement under non-workshop conditions. This could be achieved by a special encapsulation of the memory module by robust electrical connection and protection of interfaces against electro-static discharge.

The same measures for easy replacement are valid for redundant memory modules where at least one of these modules should be easily exchangeable against a module with sufficient usable lifetime. Techniques for preventative maintenance, such as end-of-life prediction and preventative replacement of memory modules, may be used to avoid data losses and corrupted data structures in the memory modules.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Set forth below are some embodiments of the foregoing disclosure:

### Embodiment 1

A high-temperature memory module used in a well operation, the memory module comprising: a control unit configured to receive data from a controller in the well operation and further configured to receive an operating temperature downhole in the well operation and to cause the control unit to initiate a shutdown of the memory module if the operating temperature is greater than a first threshold; and a memory controller configured to receive the data from the control unit and to commit the data to storage medium.

### Embodiment 2

The memory module of any prior embodiment, wherein the control unit is configured to transmit a warning to a user if the operating temperature is greater than a second threshold, wherein the first threshold is greater than the second threshold.

### Embodiment 3

The memory module of any prior embodiment, wherein initiating the shutdown comprises causing the memory controller and the storage medium to enter a write protect mode.

### Embodiment 4

The memory module of any prior embodiment, wherein initiating the shutdown comprises causing the memory module to enter an off mode.

### Embodiment 5

The memory module of any prior embodiment, wherein the memory controller is a NAND flash memory controller, and wherein the storage medium is a NAND flash storage medium.

### Embodiment 6

The memory module of any prior embodiment, wherein the memory controller is configured to provide bad block handling for the storage medium.

### Embodiment 7

The memory module of any prior embodiment, wherein the memory controller is configured to provide wear leveling for the storage medium.

### Embodiment 8

The memory module of any prior embodiment, wherein the memory controller is configured to provide error correction for the storage medium.

### Embodiment 9

The memory module of any prior embodiment, wherein the error correction is 12-bit error correction.

### Embodiment 10

The memory module of any prior embodiment, wherein the control unit periodically requests the operating temperature from a sensor located downhole in the well operation.

### Embodiment 11

The memory module of any prior embodiment, wherein the control unit is one of a field-programmable gate array (FPGA), an application-specific integrated circuit (ASIC), and a digital signal processing (DSP) system.

### Embodiment 12

The memory module of any prior embodiment, wherein the memory module is a first memory module and is replaceable with a second memory module.

### Embodiment 13

A method for writing and reading data via a memory module used in a well operation, the method comprising: receiving, at the memory module, write data from a controller at the well operation; writing, by a memory controller, the write data to a storage medium; receiving, via a communication interface, a request to read the data from the storage medium; transmitting, via the communication interface, the data responsive to the request; monitoring an operating temperature downhole in the well operation; and causing the memory module to initiate a shutdown of the memory module if the operating temperature is greater than a first threshold.

### Embodiment 14

The method of any prior embodiment, wherein the operating temperature and at least one status bit of the memory controller are utilized to calculate an estimated lifetime prediction for the memory module.

### Embodiment 15

The method of any prior embodiment, wherein the operating temperature and at least one status bit of the memory controller are utilized to determine a next maintenance cycle of the memory module.

### Embodiment 16

The method of any prior embodiment, wherein the operating temperature and at least one status bit of the memory controller are utilized to indicate a health status of the memory module.

### Embodiment 17

The method of any prior embodiment, wherein a temperature controller is configured to transmit a warning to a user if the operating temperature is greater than a second threshold, wherein the first threshold is greater than the second threshold.

### Embodiment 18

The method of any prior embodiment, wherein initiating the shutdown comprises causing the memory module and the storage medium to enter a write protect mode.

### Embodiment 19

A high-temperature memory module used in a well operation, the memory module comprising: a control unit and memory controller configured to receive data from a controller in the well operation and further configured to receive an operating temperature downhole in the well operation and to cause the control unit to initiate a shutdown of the memory module if the operating temperature is greater than a first threshold.

The descriptions of the various examples of the present disclosure have been presented for purposes of illustration, but are not intended to be exhaustive or limited to the embodiments disclosed. Many modifications and variations will be apparent to those of ordinary skill in the art without departing from the scope and spirit of the described techniques. The terminology used herein was chosen to best explain the principles of the present techniques, the practical application or technical improvement over technologies found in the marketplace, or to enable others of ordinary skill in the art to understand the techniques disclosed herein.

Additionally, the term “about” is intended to include the degree of error associated with measurement of the particular quantity based upon the equipment available at the time of filing the application. For example, “about” can include a range of ±8% or 5%, or 2% of a given value.

While one or more embodiments have been shown and described, modifications and substitutions may be made thereto without departing from the spirit and scope of the invention. Accordingly, it is to be understood that the present invention has been described by way of illustrations and not limitation.

What is claimed is:

1. A high-temperature memory module used in a well operation, the memory module comprising:
a control unit configured to receive data from a controller in the well operation and further configured to receive an operating temperature downhole in the well operation and to cause the control unit to initiate a shutdown of the memory module if the operating temperature is greater than a first threshold; and
a memory controller configured to receive the data from the control unit and to commit the data to storage medium.

2. The memory module of claim 1, wherein the control unit is configured to transmit a warning to a user if the operating temperature is greater than a second threshold, wherein the first threshold is greater than the second threshold.

3. The memory module of claim 1, wherein initiating the shutdown comprises causing the memory controller and the storage medium to enter a write protect mode.

4. The memory module of claim 3, wherein initiating the shutdown comprises causing the memory module to enter an off mode.

5. The memory module of claim 1, wherein the memory controller is a NAND flash memory controller, and wherein the storage medium is a NAND flash storage medium.

6. The memory module of claim 1, wherein the memory controller is configured to provide bad block handling for the storage medium.

7. The memory module of claim 1, wherein the memory controller is configured to provide wear leveling for the storage medium.

8. The memory module of claim 1, wherein the memory controller is configured to provide error correction for the storage medium.

9. The memory module of claim 8, wherein the error correction is 12-bit error correction.

10. The memory module of claim 1, wherein the control unit periodically requests the operating temperature from a sensor located downhole in the well operation.

11. The memory module of claim 1, wherein the control unit is one of a field-programmable gate array (FPGA), an application-specific integrated circuit (ASIC), and a digital signal processing (DSP) system.

12. The memory module of claim 1, wherein the memory module is a first memory module and is replaceable with a second memory module.

13. A method for writing and reading data via a memory module used in a well operation, the method comprising:
receiving, at the memory module, write data from a controller at the well operation;
writing, by a memory controller, the write data to a storage medium;
receiving, via a communication interface, a request to read the data from the storage medium;
transmitting, via the communication interface, the data responsive to the request;
monitoring an operating temperature downhole in the well operation; and
causing the memory module to initiate a shutdown of the memory module if the operating temperature is greater than a first threshold.

14. The method of claim 13, wherein the operating temperature and at least one status bit of the memory controller are utilized to calculate an estimated lifetime prediction for the memory module.

15. The method of claim 13, wherein the operating temperature and at least one status bit of the memory controller are utilized to determine a next maintenance cycle of the memory module.

16. The method of claim 13, wherein the operating temperature and at least one status bit of the memory controller are utilized to indicate a health status of the memory module.

17. The method of claim 13, wherein a temperature controller is configured to transmit a warning to a user if the operating temperature is greater than a second threshold, wherein the first threshold is greater than the second threshold.

18. The method of claim 13, wherein initiating the shutdown comprises causing the memory module and the storage medium to enter a write protect mode.

19. A high-temperature memory module used in a well operation, the memory module comprising:
a control unit and memory controller configured to receive data from a controller in the well operation and further configured to receive an operating temperature downhole in the well operation and to cause the control unit to initiate a shutdown of the memory module if the operating temperature is greater than a first threshold.
